(19) United States
(12) Patent Application Publication
(10) Pub. No.: US 2009/0045797 A1
(43) Pub. Date: Feb. 19, 2009

(54) MEASURING APPARATUS FOR POWER LOSS OF MAGNETIC DEVICE

(75) Inventors: Jun-Feng Guan, Taoyuan Hsien (TW); Wei Chen, Taoyuan Hsien (TW); Yi-Fan Wu, Taoyuan Hsien (TW)

Correspondence Address: KIRTON AND MCCONKIE, 60 EAST SOUTH TEMPLE,, SUITE 1800, SALT LAKE CITY, UT, 84111, US

(73) Assignee: DELTA ELECTRONICS, INC., Taoyuan Hsien (TW)

(21) Appl. No.: 12/015,225

(22) Filed: Jan. 16, 2008

(30) Foreign Application Priority Data
Aug. 17, 2007 (TW) 096130465

(51) Int. Cl. G01R 21/06

(52) U.S. Cl. 324/76.11

(57) ABSTRACT

A measuring apparatus for measuring power loss of magnetic device is disclosed. The measuring apparatus includes a power converter, a voltage measuring device and a current measuring device. The power converter is connected to the DC power supply and the magnetic device for converting the DC voltage supplied by the DC power supply into a rectangular wave alternating between positive and negative for use by the magnetic device. The voltage measuring device is connected in parallel with the DC power supply for measuring the input voltage of the power converter. The current measuring device is connected in series between the DC power supply and the power converter for measuring the input current of the power converter. The power loss of the magnetic device is substantially equal to the product of the input voltage and input current of the power converter.

### FIELD OF THE INVENTION

The present invention is related to a measuring apparatus, and more particularly to a measuring apparatus for power loss of magnetic device.

### BACKGROUND OF THE INVENTION

Magnetic devices, such as transformers or inductors, are important devices for a variety of electronic devices. The quality of the magnetic device can affect the operation and performance of electronic devices. Thus, it is important to measure the power loss of magnetic devices to acquire the accurate property of the magnetic devices.

Referring to FIG. 1, the measuring apparatus for measuring the power loss of magnetic device according to the prior art is shown. As indicated in FIG. 1, the conventional measuring apparatus employs a sinusoidal wave to measure the power loss of a magnetic device 11. The conventional measuring apparatus shown in FIG. 1 includes a sinusoidal wave generator 12, a high-frequency voltage amplifier 13, and a measuring instrument 14. The principle for measuring the power loss of magnetic device by the conventional measuring apparatus is described as follows. First, the sinusoidal wave generator 12 sends a sine wave or a cosine wave to the high-frequency voltage amplifier 13, and then the high-frequency voltage amplifier 13 amplifies the sine wave or cosine wave and outputs the amplified wave to the magnetic device 11. In the meantime, the measuring instrument 14 measures the current signal I and the voltage signal V of the magnetic device 11, wherein the current signal I and the voltage signal V are separated by a phase difference 0, and the power loss P of the magnetic device 11 can be calculated by the following equation of: P=V×I×cos θ. In practical situations, the voltage signal V of the magnetic device 11 can be obtained by measuring the voltage of the other side of the magnetic device 11 (not shown). However, such conventional measuring technique has the following disadvantages:

1. High cost: Because a sophisticated sinusoidal wave generator 12, high-frequency amplifier 13 and measuring instruments 14 with a high bandwidth are used, the cost of the conventional measuring apparatus is high.

2. Strict measuring environment: Once the sophisticated measuring apparatus is employed, the measuring apparatus has to be operated under a specific temperature and humidity, which in turn increases the cost of the measuring apparatus.

3. Intense electromagnetic wave: When the sine wave or cosine wave sent by the sinusoidal wave generator 12 is amplified by the high-frequency voltage amplifier 13, an intense electromagnetic wave would be induced. The intense electromagnetic wave is detrimental to instrument and operator, and thus the cost of electromagnetic protection equipment has to be increased.

4. Large power consumption: The sinusoidal wave generator 12, the high-frequency voltage amplifier 13 and the measuring instrument 14 all need power to operate. The power loss of these elements during measurement will exceed the power loss of the magnetic device 11, and thereby causing additional power loss.

Referring to FIG. 2, another measuring apparatus for measuring the power loss of magnetic device according to the prior art is shown. As indicated in FIG. 2, such conventional measuring technique is carried out by placing the magnetic device in an insulating medium 21, such as deionizing water or insulating oil. When an external power source 22 is supplying power to the magnetic device 11, the magnetic device 11 will suffer power loss. The power loss P of the magnetic device 11 will be transformed into heat and cause the temperature of the insulating medium 21 to rise. Because the insulating medium 21 and the magnetic device 11 are placed in a thermal insulation container 23, the heat will not leak or increase. Hereinafter, an agitator 24 is used to uniform the temperature of the insulating medium 21 within the thermal insulation container 23. In the meantime, a thermometer 25 can be used to measure the temperature of the insulating medium 21, and thus the temperature change ΔT of the insulating medium 21 can be obtained. Therefore, the power loss P of the magnetic device 11 can be obtained by the following equation of: P=ΔT×C×M/Δt, where C is the specific heat of the insulating medium 21, M is the mass of the insulating medium 21, and Δt is the time of measurement. However, such measuring technique bears the following disadvantages:

1. Low measuring accuracy: The working temperature of the magnetic device 11 is limited, and thus the allowable temperature rise of the insulating medium 21 is limited. Therefore, the measuring accuracy is relatively low. Besides, the temperature of the insulating medium 21 within the thermal insulating container 23 is difficult to maintain uniform. In this way, the measured temperature is different from location to location, and thus the measuring accuracy will be low.

2. Long measuring period: The insulating medium 21 has to be replaced every time when the measuring process is finished. Otherwise, the high-temperature insulating medium 21 has to be cooled down in order to measure the next magnetic device. Therefore, the measuring process is quite time-consuming.

3. Easy to cause human error: It is possible that each step of the measuring process would cause error, so the operator is required to possess proficient handling technique.

Therefore, there is an urgent need to develop a measuring apparatus for power loss of magnetic device to remove the foregoing drawbacks.

### SUMMARY OF THE INVENTION

An object of the present invention is to provide a measuring apparatus for power loss of magnetic device with a low cost and loose measuring environment, while only a portion of the circuits within the measuring apparatus consumes power. Therefore, the inventive measuring apparatus can remove the drawback that the measuring apparatus consumes a great quantity of power during measurement, thereby reducing power loss. Moreover, the inventive measuring apparatus takes a shortened measuring period and is adapted for the quality control of magnetic devices without complicated measuring steps. Hence, the inventive measuring apparatus does not require a proficient operator to handle the measuring process.

To this end, a broader aspect of the present invention is associated with a measuring apparatus for power loss of magnetic device. The inventive measuring apparatus includes a power converter connected with a DC power supply and a magnetic device for converting a DC voltage supplied by the DC power supply into a rectangular wave alternating between positive and negative, so that the voltage across the magnetic device can be varied between positive and negative; a voltage measuring device connected in parallel with the DC power supply for measuring the input voltage of the power converter; and a current measuring device connected in parallel between the DC power supply and the power converter for measuring the input current of the power converter. The power loss of the magnetic device is substantially the product of the input voltage of the power converter and the input current of the power converter, and thus the measuring apparatus can obtain the power loss of the magnetic device by the product of the input voltage of the power converter and the input current of the power converter.

Now the foregoing and other features and advantages of the present invention will be best understood through the following descriptions with reference to the accompanying drawings, wherein:

### BRIEF DESCRIPTION OF THE DRAWINGS

FIG. 1 is a plan view showing the structure of a measuring apparatus according to the prior art;

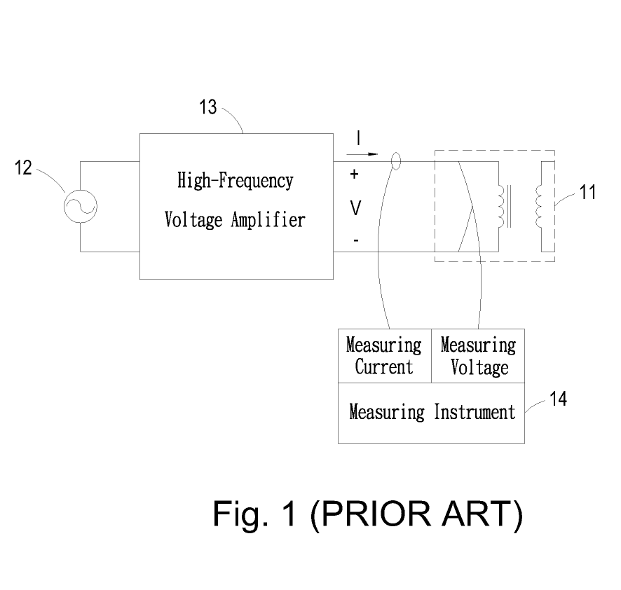

FIG. 2 is a plan view showing the structure of another measuring apparatus according to the prior art;

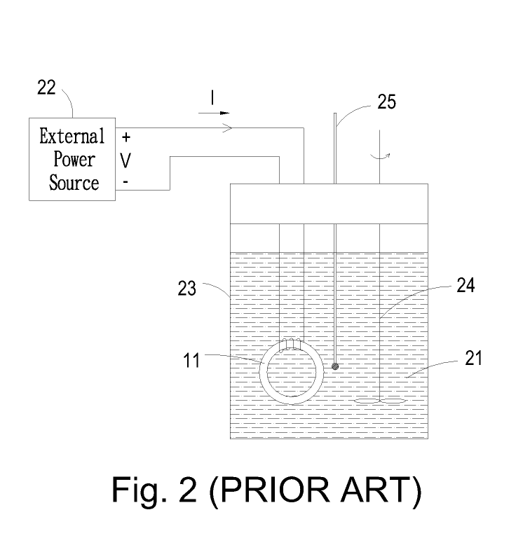

FIG. 3(a) is a circuit diagram showing the structure of a measuring apparatus according to a first embodiment of the present invention;

FIG. 3(b) is a circuit diagram showing the structure of a measuring apparatus according to an alternative embodiment of the present invention;

FIG. 4 is a timing diagram showing the timings of the first control signal, the voltage and the current of the measuring apparatus according to the present invention;

FIG. 5 is a circuit diagram showing the structure of the switch circuit within the measuring apparatus according to a second embodiment of the present invention;

FIG. 6 is a circuit diagram showing the structure of the switch circuit within the measuring apparatus according to a third embodiment of the present invention;

FIG. 7 is a circuit diagram showing the structure of the switch circuit within the measuring apparatus according to a fourth embodiment of the present invention;

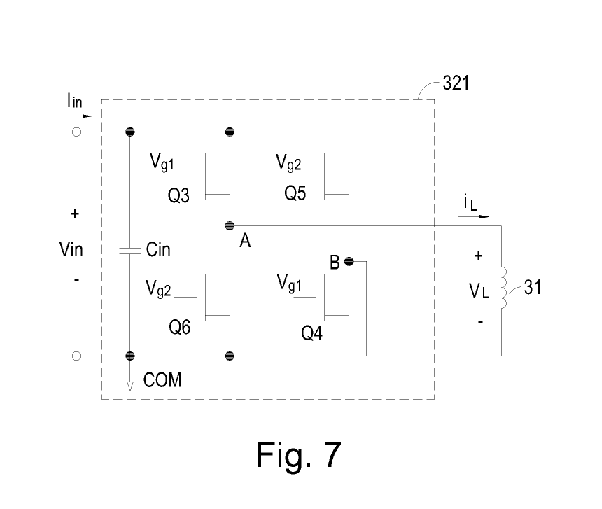

FIG. 8 is a circuit diagram showing the structure of the switch circuit within the measuring apparatus according to a fifth embodiment of the present invention;

FIG. 9 is a circuit diagram showing the structure of the switch circuit within the measuring apparatus according to a sixth embodiment of the present invention; and

FIG. 10 is a timing diagram showing the timings of the third control signal, the voltage and the current of the measuring apparatus according to the present invention.

### DETAILED DESCRIPTION OF THE PREFERRED EMBODIMENT

Several preferred embodiments embodying the features and advantages of the present invention will be expounded in following paragraphs of descriptions. It is to be realized that the present invention is allowed to have various modification in different respects, all of which are without departing from the scope of the present invention, and the description herein and the drawings are to be taken as illustrative in nature, but not to be taken as limitative.

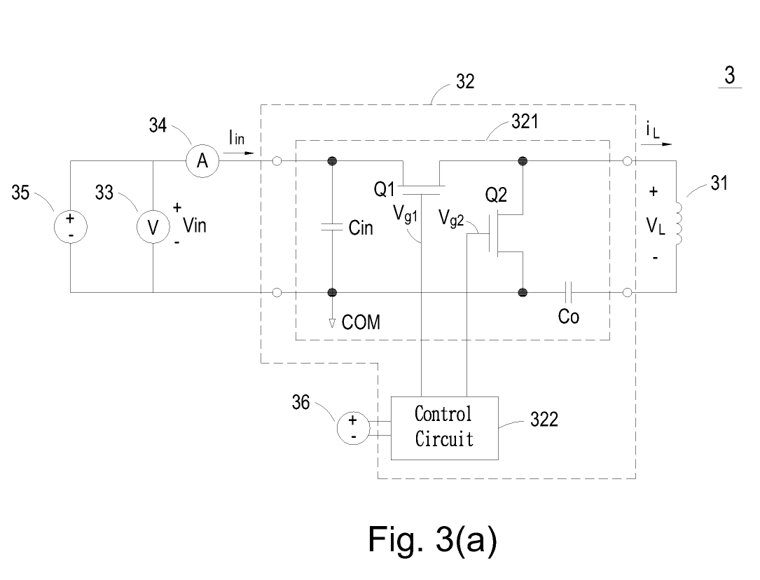

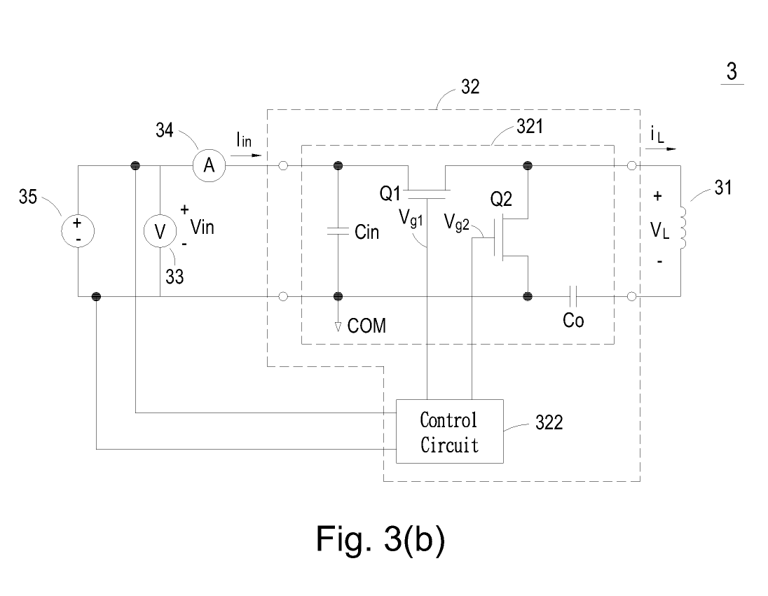

Referring to FIG. 3(a), the measuring apparatus for power loss of magnetic device according to the present invention is shown. As shown in FIG. 3(a), the measuring device according to the present invention includes a power converter 32, a voltage measuring device 33, a current measuring device 34, and a first DC power supply 35, in which the power converter 32 is connected to the first DC power supply 35 and a magnetic device 31. The power converter 32 is configured to convert the DC voltage supplied by the first DC power supply 35 into a rectangular wave alternating between positive to negative. The rectangular wave is supplied to the magnetic device 31, and thus the voltage across the magnetic device 31 is varied from positive to negative. The power converter 32 includes a switch circuit 321 and a control circuit 322, in which the control circuit 322 controls the operation of a portion of the switch circuit 321, so that the voltage across the magnetic device 31 is varied from positive to negative. This can benefit the measurement of the power loss of the magnetic device 31.

When the measuring apparatus 3 is operating, the information of the input voltage Vin and the input current Iin of the power converter 32 can be acquired through the voltage measuring device 33 connected in parallel with the first DC power supply 35 and the current measuring device 34 connected in series between the first DC power supply 35 and the power converter 32. The control circuit 322 is powered by a second DC power supply 36 and the switch circuit 321 is operating with a zero-voltage-switched (ZVS) mechanism, and thus the input power of the power converter 32 is substantially equal to the output power of the power converter 32. Therefore, the power loss P of the magnetic device 31 is substantially equal to the input power of the power converter 32, and thus the power loss P of the magnetic device 31 can be calculated by the equation of: P=Vin×Iin. In addition, the voltage measuring device 33 and the current measuring device 34 are configured to measure the input voltage Vin and the input current Iin of the power converter 32, so that the power loss P of the magnetic device 31 can be obtained. Therefore, the voltage measuring device 33 and the current measuring device 34 can be replaced with a power measuring device (not shown) that can measure the power loss P of the magnetic device 31.

Referring to FIG. 3(a), the power converter 32 within the measuring apparatus 3 includes a switch circuit 321 and a control circuit 322, wherein the switch circuit 321 includes an input capacitor Cin, a first switch element Q1, a second switch element Q2, and an output capacitor Co. The input capacitor Cin is connected in parallel with the DC input side of the power converter 32 and a common node COM for filtering. One end of the first switch element Q1 is connected to the DC input side of the power converter 32, and the other end of the first switch element Q1 is connected to the output side of the power converter 32. The first switch element Q1 is regulated by the first control signal Vg1 issued by the control circuit 322. The second switch element Q2 is connected in parallel with the DC input side of the power converter 32 and the common node COM, and is regulated by the second control signal Vg2 issued by the control circuit 322. In addition, the output capacitor Co is connected in series between the common node COM and the output side of the power converter 32.

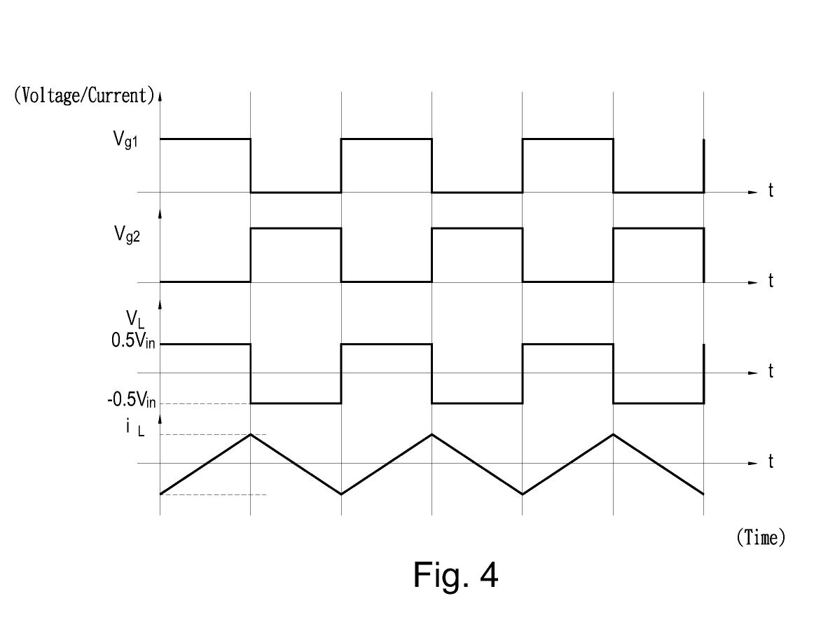

Referring to FIG. 3(a) and FIG. 4, the timings of the first control signal, the voltage and the current of the magnetic device are shown in FIG. 4. The control circuit 322 is configured to respectively control the on/off operation of the first switch element Q1 and the second switch element Q2 by the first control signal Vg1 and the second control signal Vg2, as shown in FIG. 4. In the present embodiment, the duty cycle of the first control signal Vg1 and the duty cycle of the second control signal Vg2 are respectively 50%, for example. That is, the high-level duration and low-level duration respectively occupy one half period. Certainly, the duty cycle of the first control signal Vg1 and the duty cycle of the second control signal Vg2 can be flexibly allocated according to user's demands. Also, in order to allow the switch circuit 321 to perform zero-voltage switching, a short dead time will exist at the transient of the first control signal Vg1 and the second control signal Vg2. During the dead time, the first control signal Vg1 and the second control signal Vg2 are both at the low level. Because the dead time is too short, it is not depicted in FIG. 4. When the control circuit 322 manipulates the first control signal Vg1 to be at a high level, the first switch element Q1 will turn on. At the same time, the output voltage of the power converter 32 will be the voltage V_{L} across the magnetic element 31. In the present embodiment, the voltage V_{L} across the magnetic element 31 is 0.5 Vin. When the control circuit 322 manipulates the second control signal Vg2 to be at a high level, the second switch element Q2 will turn on. At the same time, the voltage V_{L} across the magnetic element 31 is −0.5 Vin it is to be noted that the first control signal Vg1 and the second control signal Vg2 are continuously fluctuating between the high level and the low level, so that the power converter 32 will output rectangular wave alternating between positive and negative to the magnetic element 31, wherein the duty cycle of the rectangular wave is substantially ranged from 0 to 1. The magnetic element 31 can induce a current i_{L} in response to the oscillation of the rectangular wave, and the current i_{L} should be a triangular wave due to the characteristics of the magnetic element 31. At the same time, the magnetic core of the magnetic element 31 will generate a triangular flux accordingly and cause power loss. The control circuit 322 is powered by the second DC power supply 36 and the power loss of the switch circuit 321 is too small, and thus the power loss P of the magnetic device 31 is substantially equal to the input power of the power converter 32. Therefore, the power loss P of the magnetic device 31 can be obtained by measuring the input power of the power converter 32. Certainly, the control circuit can be powered by the first DC power supply 35 as shown in FIG. 3(b). Under this condition, the measurement of the power loss P of the magnetic device 31 and the measurement of the input power of the power converter 32 will not be affected.

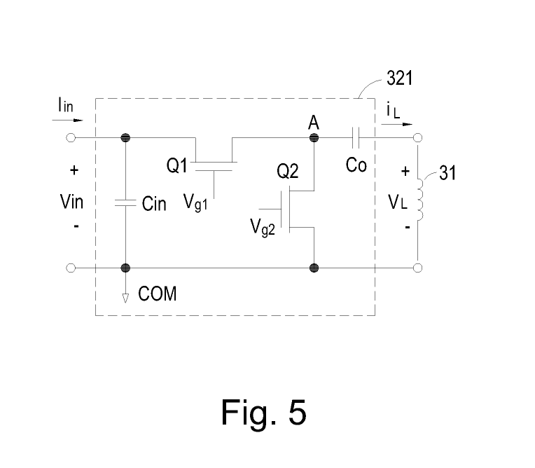

Referring to FIG. 5, the switch circuit within the measuring apparatus for power loss of magnetic device according to a second embodiment of the present invention is shown. As shown in FIG. 5, the switch circuit 321 of the power converter 32 includes an input capacitor Cin, a first switch element Q1, a second switch element Q2, and an output capacitor Co, wherein each element has the same function and structure as the counterpart element disclosed in the previous embodiment. However, the output capacitor Co is connected between the first switch element Q1 and the output side of the power converter 32 in the present embodiment for filtering out the DC component of the output voltage, so that the voltage V_{L} across the magnetic device 31 is a rectangular wave without any DC component. The current i_{L} of the magnetic device 31 is a triangular wave as well, and the magnetic core of the magnetic device 31 will generate a corresponding triangular flux and cause power loss. Therefore, the power loss P of the magnetic device 31 is substantially equal to the input power of the power converter 32, thereby obtaining the power loss P of the magnetic device 31 by measuring the input power of the power converter 32.

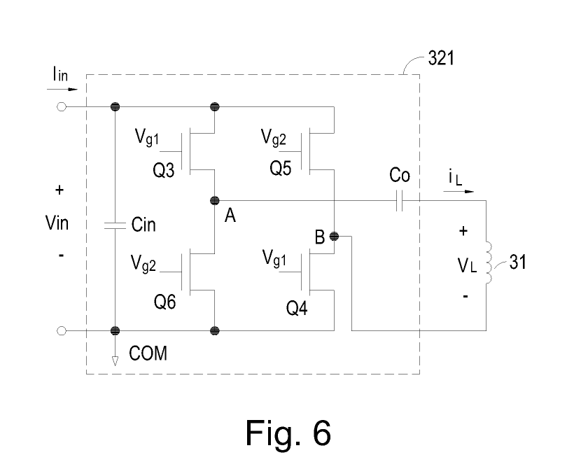

Referring to FIG. 6, the switch circuit within the measuring apparatus for power loss of magnetic device according to a third embodiment of the present invention is shown. As shown in FIG. 6, the switch circuit 321 of the power converter 32 includes an input capacitor Cin, a third switch element Q3, a fourth switch element Q4, a fifth switch element Q5, a sixth switch element Q6, and an output capacitor Co, wherein the input capacitor Cin is connected in parallel with the DC input side of the power converter 32 and a common node COM for filtering. The third switch element Q3 and the sixth switch element Q6 are connected in series with node A, and the other end of the third switch element Q3 and the other end of the sixth switch element Q6 are respectively connected to the first DC power supply 35. The fifth switch element Q5 and the fourth switch element Q4 are connected in series with node B, and the other end of the fifth switch element Q5 and the other end of the fourth switch element Q4 are respectively connected to the first DC power supply 35 and the common node COM. The output capacitor Co is connected between the node A and the switch circuit 321 for filtering out the DC component of the output voltage. The control circuit 322 employs the first control signal Vg1 and the second control signal Vg2 to manipulate the operation of the switch circuit 321. When the first control signal Vg1 is at a high level, the third switch element Q3 and the fourth switch element Q4 will turn on. When the second control signal Vg2 is at a high level, the fifth switch element Q5 and the sixth switch element Q6 will turn on, so that the voltage V_{L} across the magnetic device 31 is a rectangular wave having a peak voltage of ±0.5 Vin without any DC component. That is, the voltage V_{L} across the magnetic device 31 is a rectangular wave having a mean value of zero. The current i_{L} of the magnetic device 31 is a triangular wave as well, and the magnetic core of the magnetic device 31 will generate a corresponding triangular flux and cause power loss. Therefore, the power loss P of the magnetic device 31 is substantially equal to the input power of the power converter 32, thereby obtaining the power loss P of the magnetic device 31 by measuring the input power of the power converter 32. In alternative embodiments, the output capacitor Co can be removed, and the duty cycle of the rectangular wave can be 50% under this condition.

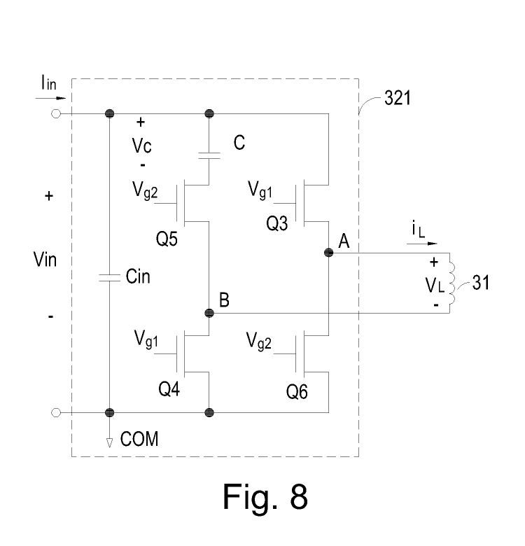

Referring to FIG. 8, the switch circuit within the measuring apparatus for power loss of magnetic device according to a fifth embodiment of the present invention is shown. As shown in FIG. 8, the switch circuit 321 of the power converter 32 includes an input capacitor Cin, a third switch element Q3, a fourth switch element Q4, a fifth switch element Q5, a sixth switch element Q6, and a first capacitor C, wherein the input capacitor Cin is connected in parallel with the DC input side of the power converter 32 for filtering. The third switch element Q3 and the sixth switch element Q6 are connected in series with node A, and the other end of the third switch element Q3 and the other end of the sixth switch element Q6 are respectively connected to the first DC power supply 35 and the common node COM. The fifth switch element Q5 and the fourth switch element Q4 are connected in series with node B and then connected to the first capacitor C, and the other end of the fourth switch element Q4 and the other end of the first capacitor C are respectively connected to the first DC power supply 35. The voltage Vc of the first capacitor C will vary in accordance with the duty cycle of the first control signal Vg1 and the duty cycle of the second control signal Vg2. When the duty cycle is 50%, the voltage Vc of the first capacitor C will be zero. When the first control signal Vg1 is at a high level, the third switch element Q3 and the fourth switch element Q4 will turn on, and voltage V_{L} across the magnetic element 31 will be Vin. In addition, when the second control signal Vg2 is at a high level, the fifth switch element Q5 and the sixth switch element Q6 will turn on, and voltage V_{L} across the magnetic element 31 will be −Vin+Vc. Therefore, the voltage V_{L} across the magnetic element 31 will be a rectangular wave having a DC component, that is, a rectangular wave having a mean value of Vc. The current i_{L} of the magnetic device 31 will be a triangular wave as well, and the magnetic core of the magnetic device 31 will generate a corresponding triangular flux and cause power loss. Therefore, the power loss P of the magnetic device 31 is substantially equal to the input power of the power converter 32, thereby obtaining the power loss P of the magnetic device 31 by measuring the input power of the power converter 32.

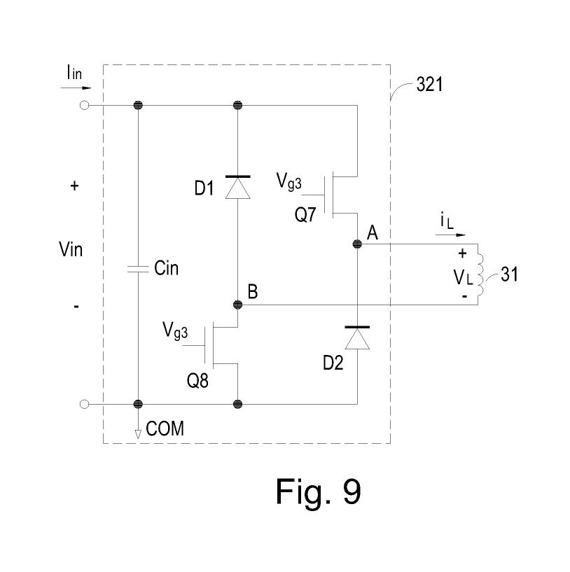

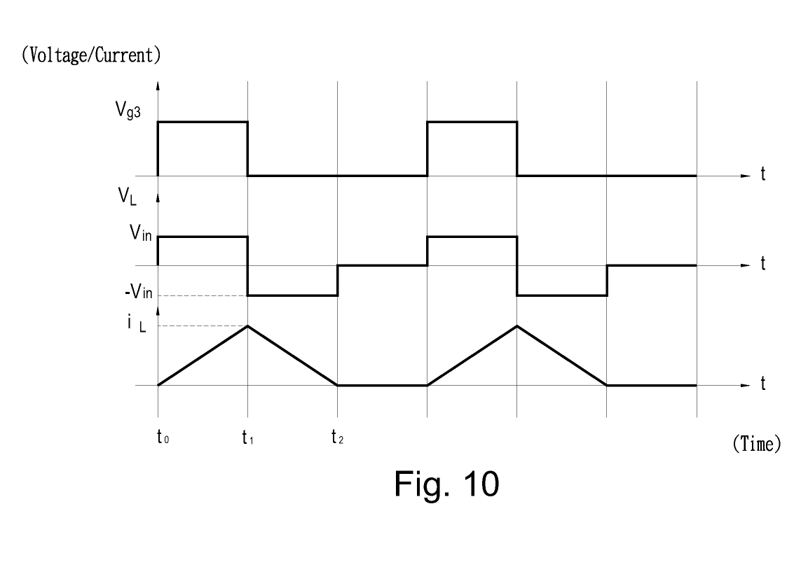

Referring to FIG. 9, the switch circuit within the measuring apparatus for power loss of magnetic device according to a sixth embodiment of the present invention is shown. As shown in FIG. 9, the switch circuit 321 of the power converter 32 includes an input capacitor Cin, a seventh switch element Q7, an eighth switch element Q8, a first diode D1, and a second diode D2, wherein the input capacitor Cin is connected in parallel with the DC input side of the power converter 32 and the common node COM for filtering. The seventh switch element Q7 and the second diode D2 are connected in series with node A, and the other end of the seventh switch element Q7 and the other end of the second diode D2 are respectively connected to the first DC power supply 35 and the common node COM. The first diode D1 and the eighth switch element Q8 are connected in series with node B, and the other end of the first diode D1 and the other end of the eighth switch element Q8 are respectively connected to the first DC power supply 35 and the common node COM. FIG. 10 shows the timings of the third control signal issued by the control circuit and the timing of the voltage and current of the magnetic device. As shown in FIG. 10, during time t0 to t1, the third control signal Vg3 is at a high level, and the seventh switch element Q7 and the eighth switch element Q8 are turned on, and the voltage V_{L} across the magnetic device 31 is Vin accordingly. During time t1 to t2, the third control signal Vg3 is at a low level, and the seventh switch element Q7 and the eighth switch element Q8 are turned off. Under this condition, the first diode D1 and the second diode D2 are turned on due to the afterflow effect of the magnetic device 31. Therefore, the voltage V_{L} across the magnetic device 31 is −Vin and the current i_{L} of the magnetic device 31 drops linearly until zero. When the current i_{L} of the magnetic device 31 drops to zero, the first diode D1 and the second diode D2 are turned off. Therefore, the voltage V_{L} across the magnetic device 31 is a non-continuous rectangular wave, and the current i_{L} of the magnetic device 31 is a non-continuous triangular wave. Therefore, the magnetic core of the magnetic device 31 will generate a non-continuous triangular flux and cause power loss. Therefore, the power loss P of the magnetic device 31 is substantially equal to the input power of the power converter 32, thereby obtaining the power loss P of the magnetic device 31 by measuring the input power of the power converter 32.

In conclusion, the inventive measuring apparatus for power loss of magnetic device utilizes a sophisticated power converter 32, a voltage measuring device 33, a current measuring device 34 and a first DC power supply 35 that are inexpensive and does not require a strict measuring environment. Moreover, the circuits within the measuring apparatus will not consume power except the control circuit 322. Therefore, the drawback that the measuring apparatus will consume a large quantity of power during measurement can be removed. Besides, the measuring period spent by the measuring apparatus according to the present invention is quite short, and thus the measuring apparatus according to the present invention is adapted for quality control of the magnetic device without complicated measuring steps.

Those of skilled in the art will recognize that these and other modifications can be made within the spirit and scope of the present invention as further defined in the appended claims.

What is claimed is:

1. A measuring apparatus for measuring the power loss of a magnetic device, comprising:
a power converter connected to a DC power supply and the magnetic device for converting a DC voltage supplied by the DC power supply into a rectangular wave alternating between positive and negative and supplying the DC voltage to the magnetic device, such that a voltage across the magnetic device varies between positive and negative;
a voltage measuring device connected in parallel with the DC power supply for measuring an input voltage of the power converter; and
a current measuring device connected in series between the DC power supply and the power converter for measuring an input current of the power converter;
wherein the power loss of the magnetic device is obtained by measuring the product of the input voltage of the power converter and the input current of the power converter.

2. The measuring apparatus according to claim 1 wherein the power converter comprises:
a switch circuit having at least one switch element and connected to an input side and an output side of the power converter; and
a control circuit connected to the switch circuit for controlling on/off operation of switch elements within the switch circuit;
wherein the control circuit of the power converter is powered by the DC power supply or another DC power supply.

3. The measuring apparatus according to claim 2 wherein the switch circuit comprises:
an input capacitor connected in parallel with the input side of the power converter and a common node for filtering;
a first switch element having one end connected to the input side of the power converter and the other end connected to the output side of the power converter and being manipulated to turn on and off by the control circuit;
a second switch element connected in parallel with the output side of the power converter and the common node and being manipulated to turn on and off by the control circuit; and
an output capacitor connected between the common node and the output side of the power converter, or connected between the first switch element and the output side of the power converter.

4. The measuring apparatus according to claim 2 wherein the switch circuit comprises:
an input capacitor connected in parallel with the input side of the power converter and a common node for filtering;
a third switch element connected to the input capacitor and the DC power supply;
a fourth switch element connected to the common node;
a fifth switch element having one end connected to the input capacitor, the third switch element and the DC power supply and the other end connected to the fourth switch element; and
a sixth switch element having one end connected to the common node and the fourth switch element and the other end connected to the third switch element;
wherein when the control circuit manipulates the third switch element and the fourth switch element to turn on, the fifth switch element and the sixth switch element are turned off, and wherein when the control circuit manipulates the fifth switch element and the sixth switch element to turn on, the third switch element and the fourth switch element are turned off.

5. The measuring apparatus according to claim 4 wherein the switch circuit further comprises an output capacitor having one end connected to the third switch element and the sixth switch element and the other end connected to the output side of the power converter.

6. The measuring apparatus according to claim 4 wherein the switch circuit further comprises a first capacitor connected in series between the fifth switch element and the DC power supply.

7. The measuring apparatus according to claim 2 wherein the switch circuit comprises:
an input capacitor connected in parallel with the input side of the power converter and a common node for filtering;
a seventh switch element connected to the input capacitor;
an eighth switch element connected to the common node;
a first diode having one end connected to the eighth switch element and the other end connected to the DC power supply; and
a second diode having one end connected to the seventh switch element and the other end connected to the common node;
wherein when the control circuit manipulates the seventh switch element and the eighth switch element to turn on, the first diode and the second diode are turned off.

8. The measuring apparatus according to claim 2 wherein the control circuit employs a zero-voltage switching technique to control the switch circuit.

9. The measuring apparatus according to claim 1 wherein the rectangular wave has a duty cycle ranged between 0 and 1.

10. The measuring apparatus according to claim 1 wherein a current of the magnetic device is a triangular wave.

11. The measuring apparatus according to claim 1 wherein the voltage measuring device and the current measuring device are constructed in a power measuring device for measuring the power loss of the magnetic device.
